(19) United States
(12) Patent Application Publication
(10) Pub. No.: US 2026/0039280 A1
(43) Pub. Date: Feb. 5, 2026

(54) MEMORY DEVICES WITH REDUCED TIMING VARIATION AND METHODS FOR OPERATING THE SAME

(71) Applicant: Taiwan Semiconductor Manufacturing Company, Ltd., Hsinchu (TW)

(72) Inventors: Perng-Fei Yuh, Hsinchu (TW); Tomohiko Yano, Hsinchu (TW)

(73) Assignee: Taiwan Semiconductor Manufacturing Company, Ltd., Hsinchu (TW)

(21) Appl. No.: 18/794,560

(22) Filed: Aug. 5, 2024

(51) Int. Cl. G05F 3/26; G11C 5/14

(52) U.S. Cl. CPC H03K 3/0315; G05F 3/262

(57) ABSTRACT

A circuit includes a current source configured to provide a reference current and a plurality of transistors each configured to receive the reference current from the current source. Each of the plurality of transistors has a same conductive type and includes a first source/drain terminal connected to a gate terminal of a first neighboring one of the transistors, a second source/drain terminal connected to ground, and a gate terminal connected to a source/drain terminal of a second neighboring one of the transistors.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory circuit, in accordance with various embodiments.

FIG. 2 to FIG. 5 illustrate example circuits that can be included in the memory circuit, in accordance with various embodiments.

FIG. 6 illustrates waveforms of various signals associated with operation of an example circuit, in accordance with various embodiments.

FIG. 7 to FIG. 10 illustrate example circuits that can be included in the memory circuit, in accordance with various embodiments.

FIG. 11 illustrates a flow chart of an example method for operating a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, implementing an on-chip ring-oscillator (RO) for memory devices with an extended bit size is challenging because of the frequency control tolerance and the range over process corners, voltage biases, and temperatures (PVT) variation. For example, the ROs tend to be sensitive to temperature variations, which causes significant frequency drift. In such memory applications, where precise timing is desired, this instability leads to timing errors and unreliable operation. In addition, variations in manufacturing processes often result in differences in the characteristics of the ROs, affecting the frequency. This makes it difficult to maintain a consistent clock speed across different chips and operating conditions.

The present disclosure can provide techniques that allow for PVT-independent oscillation frequency, which allows for an on-chip frequency reference and a clock generator that can be insensitive to the PVT variation. This can replace an off-chip crystal oscillator and/or an on-chip phase-locked loop (PLL) combination, thereby enabling accurate frequency control and thus improving power performance, and area (PPA) of the charge pump and timing circuit.

According to the present disclosure, a circuit can include transistors connected to each other. Each of the transistors can include a first source/drain terminal connected to a gate terminal of a first neighboring one of the transistors, a second source/drain terminal connected to ground, and a gate terminal connected to a source/drain terminal of a second neighboring one of the transistors. This configuration can allow for generation of oscillating signals. In some embodiments, the transistors can be or include n-type metal-oxide-semiconductor (NMOS)-only transistors. In some embodiments, the transistors can be or include p-type MOS-only transistors. The transistors can be biased by a current source that is proportional to the threshold voltage of the corresponding transistors, which can achieve the reduction in frequency variation over the PVT.

While providing benefit for the memory technologies as discussed above, the techniques disclosed herein can be useful for various other applications such as, for example, internet-of-thing (IOT) devices. It is challenging to incorporate such a crystal oscillator and/or PLL frequency reference in IOT devices as such devices are implemented with a low power and small area. The techniques disclosed herein can provide a low-power, small area frequency reference with improved frequency control such that the IOT devices can be implemented without the use of crystal oscillators or PLLs.

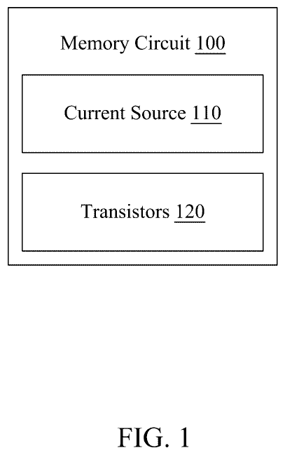

FIG. 1 illustrates a block diagram of a memory circuit 100, in accordance with various embodiments. The memory circuit 100 shown in FIG. 1 is simplified for illustration purposes, and thus, it should be appreciated that the memory circuit 100 can include any of various other components while remaining within the scope of the present disclosure.

The memory circuit 100 is a hardware component that is configured to control various operations of a memory array such as, reading data bits from memory cells, writing data bits into the memory cells, etc. In various embodiments, the memory circuit 100 can include a number of circuits, each of which may be embodied as logic circuits, analog circuits, or a combination of them, to perform such operations. In some embodiments, the memory circuit 100 can include a clock generator, a pulse generator, etc. The clock generator can receive or generate a clock signal, and provide the clock signal for the pulse generator to generate a number of clock pulses. The pulse generator can rely on the clock pulses to control (e.g., pull up and/or down) a number of control signals. In some embodiments, the memory circuit 100 can include a ring oscillator as clock generator.

In some embodiments, the memory circuit 100 can include a current source 110 and transistors 120. The current source 110 is a hardware component that is configured to provide a current. For example, the current source 110 can provide a reference current to the transistors 120. Each of the transistors 120 can be configured to receive the reference current from the current source 110. In some embodiments, the reference current can be proportional to a threshold voltage of the transistors 120. In some embodiments, the transistors 120 can have a same conductive type (e.g., n-type, p-type).

In some embodiments, each of the transistors 120 can include a first source/drain terminal connected to a gate terminal of a first neighboring one of the transistors 120, a second source/drain terminal connected to ground, and a gate terminal connected to a source/drain terminal of a second neighboring one of the transistors. In some embodiments, the transistors 120 can provide oscillating signals. For example, a first one of the transistors 120 can provide a first signal, and a second one of the transistors 120 can provide a second signal. The second signal can be a delayed version of the first signal. In some embodiments, the second signal falls in response to the first signal rising to the threshold voltage. In some embodiments, the circuit 100 can include various components, including but not limited to, a capacitor, current mirror, amplifier, etc., as discussed in greater detail below.

In some embodiments, the current source 110 and the transistors 120 can be configured to serve as a ring oscillator. For example, the transistors 120 can be configured to provide oscillating signals without connecting to an inverter.

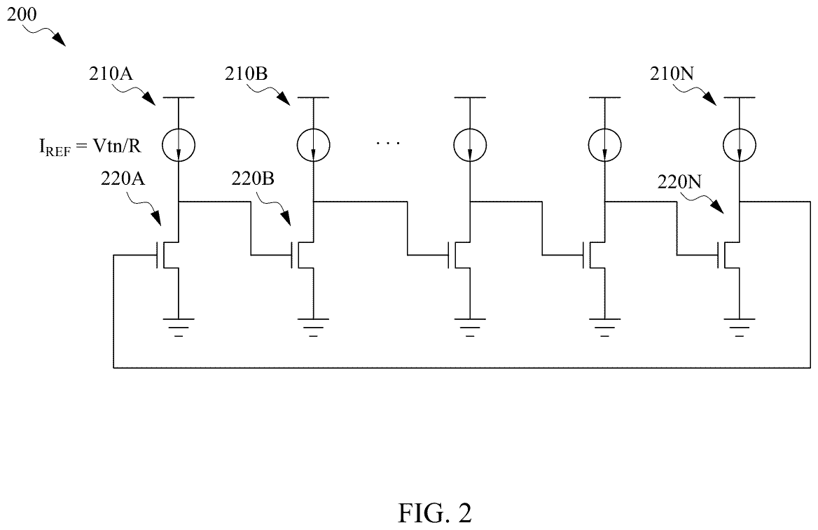

FIG. 2 illustrates an example circuit 200 that can be included in the memory circuit 100, in accordance with various embodiments. The circuit 200 can include a current source 210 (210A, 210B, . . . , 210N) and transistors 220 (220A, 220B, . . . , 220N), which may be substantially similar to and/or incorporate features of the current source 110 and the transistors 120, respectively. Shown in FIG. 2 is a non-limiting example, and the circuit 200 can include more, fewer, or different components than shown in or described with respect to FIG. 2.

The current source 210 can be configured to provide a reference current REF. In some embodiments, the reference current IREF can be proportional to a threshold voltage Vtn of the transistors 220. For example, as shown, the reference current IREF can be Vtn/R. The transistors 220 can be configured to receive the reference current IREF from the current source 210. In some embodiments, as shown, each of the transistors 220 is connected to a corresponding one of the current source 210 and receive the reference current IREF therefrom. In some embodiments, the transistors 220A, 220B, . . . , 220N can have the same threshold voltage Vtn.

In some embodiments, the transistors 220 can have a same conductive type. For example, the transistors 220 can be n-type transistors. For example, the transistors 220 can be p-type transistors. In some embodiments, the transistors 220 can include only one type of transistors. For example, each of the transistors 220 can be an n-type MOS transistor. For example, each of the transistors 220 can be a p-type MOS transistor.

In some embodiments, the transistors 220 can be or include a plurality of transistors connected to each other. In some embodiments, as shown, the transistors 220 can form a loop, such that the transistors are connected in a circular arrangement. In some embodiments, each of the transistors 220 can include a first source/drain terminal connected to a gate terminal of a first neighboring one of the transistors 220, a second source/drain terminal connected to ground, and a gate terminal connected to a source/drain terminal of a second neighboring one of the transistors 220. For example, the first source/drain terminal of the transistor 220A is connected to the gate terminal of a first neighboring transistor (e.g., the transistor 220B). The second source/drain terminal of the transistor 220A is connected to ground. The gate terminal of the transistor 220A is connected to the source/drain terminal of a second neighboring transistor (e.g., the transistors 220N).

In some embodiments, the circuit 200 can be configured to serve as a ring oscillator. The transistors 220 can be configured to provide oscillating signals. For example, the transistor 220A can be configured to provide a first signal, and the transistor 220B can be configured to provide a second signal being a delayed version of the first signal. In some embodiments, the transistors 220 can be configured to provide oscillating signals without connecting to an inverter.

Although depicted to include five transistors (e.g., N=5), the circuit 200 can include a certain number of transistors 220. In some embodiments, the number of transistors 220 can be a prime number (e.g., 2, 3, 5, 7, etc.). This can prevent two or more signals from being harmonized. In some embodiments, the number of transistors 220 can be an odd number.

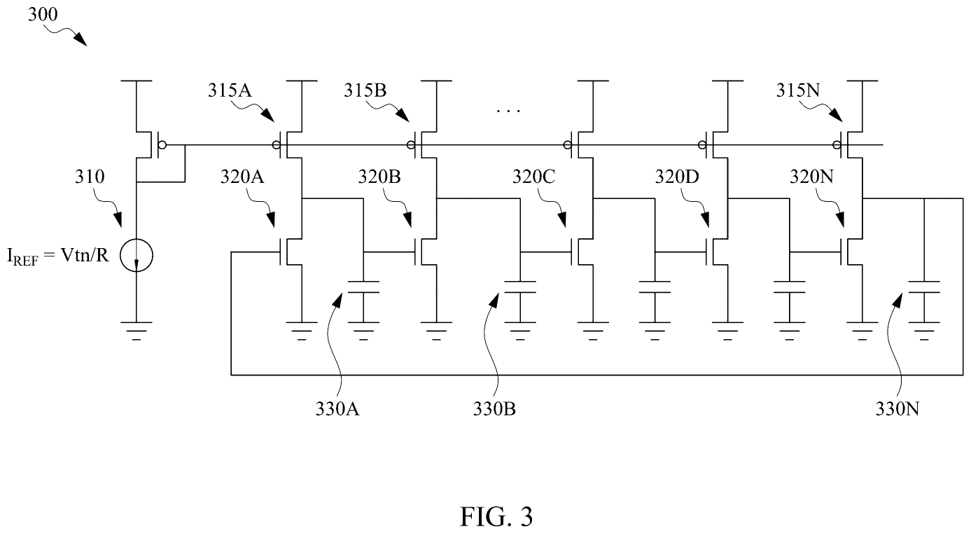

FIG. 3 illustrates an example circuit 300 that can be included in the memory circuit 100, in accordance with various embodiments. In some embodiments, the circuit 300 may be substantially similar to and/or incorporate features of the circuit 100, the circuit 200, etc. The circuit 300 can include a current source 310, first transistors 320 (320A, 320B, . . . , 320N), second transistors 315 (315A, 315B, . . . , 315N), and capacitors 330 (330A, 330B, . . . , 330N). Shown in FIG. 3 is a non-limiting example, and the circuit 300 can include more, fewer, or different components than shown in or described with respect to FIG. 3.

The current source 310 can be configured to provide a reference current IREF. In some embodiments, the current source 310 can provide the reference current IREF through a current mirror. The current mirror can be connected between the current source 310 and the first transistors 320. In some embodiments, the current mirror can include the second transistors 315. As shown, each of the second transistors 315 can be connected to a corresponding one of the first transistors 320. In some embodiments, the second transistors 315 can have a conductive type opposite to the conductive type of the first transistors 320. For example, the first transistors 320 are n-type MOS transistors, and the second transistors 315 are p-type MOS transistors.

In some embodiments, the current source 310 can provide the reference current IREF proportional to a threshold voltage Vtn of the first transistors 320 to each of the first transistors 320. For example, as shown, the reference current IREF can be Vtn/R.

In some embodiments, the first transistors 320 can be or include a plurality of transistors connected to each other, while connected to other components. In some embodiments, each of the first transistors 320 can include a first source/drain terminal connected to a gate terminal of a first neighboring one of the first transistors 320, a second source/drain terminal connected to ground, and a gate terminal connected to a source/drain terminal of a second neighboring one of the first transistors 320. For example, the first source/drain terminal of the first transistor 320A is connected to the gate terminal of a first neighboring transistor (e.g., the first transistor 320B). The second source/drain terminal of the first transistor 320A is connected to ground. The gate terminal of the first transistor 320A is connected to the source/drain terminal of a second neighboring transistor (e.g., the first transistors 320N).

In some embodiments, as shown, the capacitors 330 can be connected to the first source/drain terminal of each of the first transistors 320. The capacitors 330 can be purposedly added load capacitors. In some embodiments, as shown, the capacitors 330 can be connected to the gate terminal of each of the first transistors 320. For example, each of the first source/drain terminal of the first transistor 320A and the gate terminal of the first transistor 320B can be connected to the capacitor 330A. In some embodiments, the capacitors 330 can be omitted (e.g., as shown in FIG. 2). In some embodiments, the capacitors 330 can represent other capacitance (e.g., wire, parasitic, etc.).

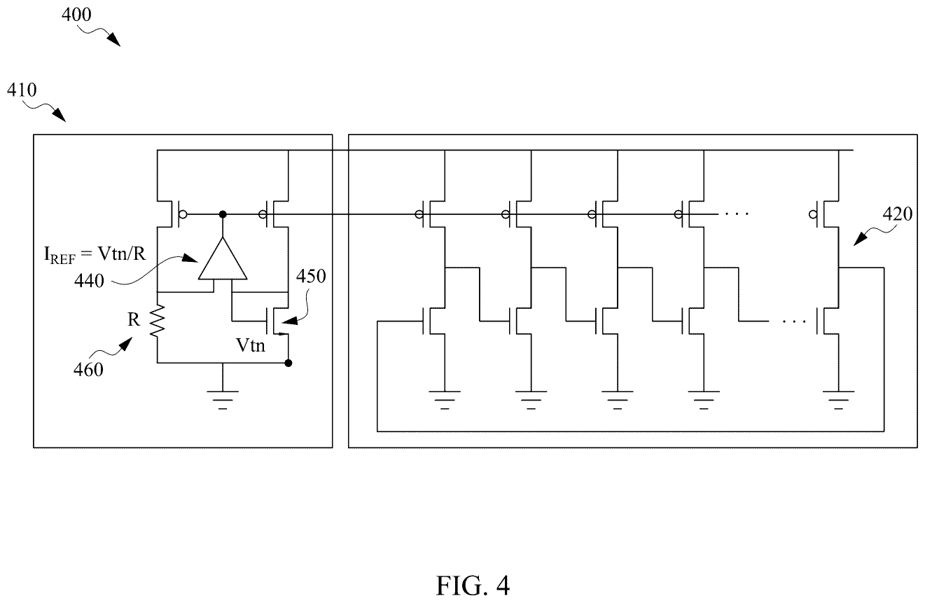

FIG. 4 illustrates an example circuit 400 that can be included in the memory circuit 100, in accordance with various embodiments. In some embodiments, the circuit 400 may be substantially similar to and/or incorporate features of the circuit 100, the circuit 200, the circuit 300, etc. The circuit 400 can include a current source 410 and transistors 420, may be substantially similar to and/or incorporate features of the current source 110 (and/or the current source 210, the current source 310, etc.) and the transistors 120 (and/or the transistors 220, the transistors 320, etc.), respectively. Shown in FIG. 4 is a non-limiting example, and the circuit 400 can include more, fewer, or different components than shown in or described with respect to FIG. 4.

The current source 410 can include various components configured to provide a reference current IREF to the transistors 420. In some embodiments, the current source 410 can include an operational amplifier 440, a diode-connected transistor 450, a resistor 460, which can be configured to provide the reference current IREF to the transistors 420. In some embodiments, as shown, the operational amplifier 440 can be connected to the diode-connected transistor 450. In some embodiments, the diode-connected transistor 450 can have a threshold voltage (Vtn), the same as the threshold voltage of the transistors 420. In some embodiments, as shown, the operational amplifier 440 can be connected to the resistor 460 having a resistance of (R), such that the operational amplifier 440 can force the voltage on top of the resistor 460 to be the threshold voltage of the diode-connected transistor 450. The operational amplifier 440 can be thereby configured to output the reference current IREF based on the threshold voltage (Vtn) of the diode-connected transistor 450. For example, the current source 410 can be configured for the operational amplifier 440 to output the reference current IREF of Vtn/R.

In some embodiments, the transistors 420 can have the same threshold voltage Vtn as the diode-connected transistor 450. The transistors 420 can be of the same type as the transistor 450. The transistors 420 can have a same size and/or a fixed ratio as that of the transistor 450. In some embodiments, the transistors 420 can be a multiple or fractional of the size of transistor 450.

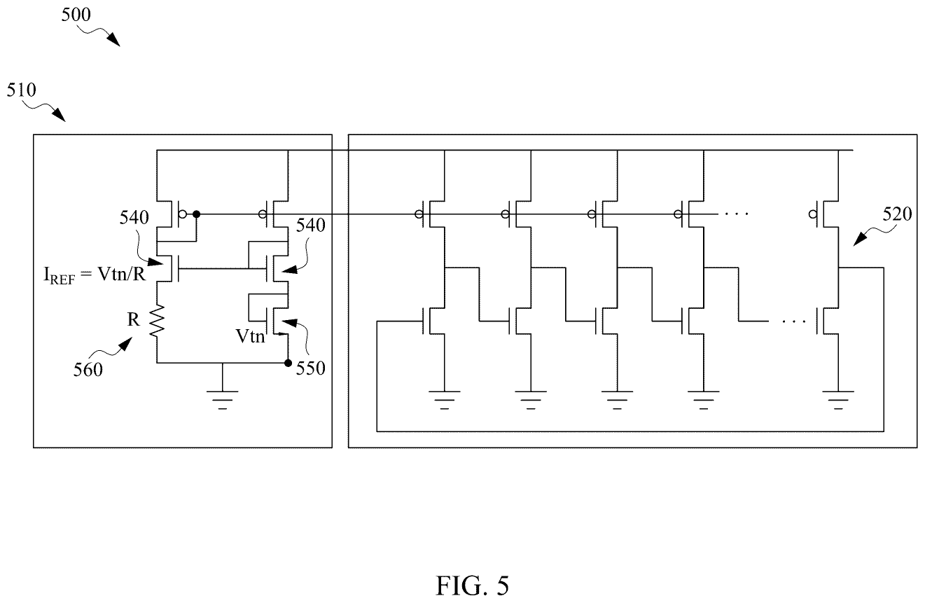

FIG. 5 illustrates an example circuit 500 that can be included in the memory circuit 100, in accordance with various embodiments. In some embodiments, the circuit 500 may be substantially similar to and/or incorporate features of the circuit 100, the circuit 200, the circuit 300, etc. The circuit 500 can include a current source 510 and transistors 520, may be substantially similar to and/or incorporate features of the current source 110 (and/or the current source 210, the current source 310, etc.) and the transistors 120 (and/or the transistors 220, the transistors 320, etc.), respectively. Shown in FIG. 5 is a non-limiting example, and the circuit 500 can include more, fewer, or different components than shown in or described with respect to FIG. 5.

The current source 510 can include various components configured to provide a reference current IREF to the transistors 520. In some embodiments, the current source 510 can include a diode-connected transistor 550, reference transistors 540, a resistor 560, which can be configured to provide the reference current IREF to the transistors 520.

In some embodiments, the reference transistors 540 can have a conductive type the same as the conductive type of the transistors 520. For example, both the transistors 520 and the reference transistors 540 are n-type MOS transistors. For example, both the transistors 520 and the reference transistors 540 are p-type MOS transistors.

In some embodiments, as shown, the reference transistors 540 can be connected to the diode-connected transistor 550. In some embodiments, the diode-connected transistor 550 can have a threshold voltage (Vtn), the same as the threshold voltage of the transistors 520. In some embodiments, as shown, the reference transistors 540 can be connected to the resistor 560 having a resistance of (R), such that the reference transistors 540 can force the voltage on top of the resistor 560 to be the threshold voltage of the diode-connected transistor 550. The current source 510 can be configured to output the reference current IREF based on the threshold voltage of the diode-connected transistor (Vtn), for example, Vtn/R.

In some embodiments, the transistors 520 can have the same threshold voltage Vtn as the diode-connected transistor 550. The transistors 520 can be of the same type as the transistor 550. The transistors 520 can have a same size and/or a fixed ratio as that of the transistor 550. In some embodiments, the transistors 520 can be a multiple or fractional of the size of transistor 550.

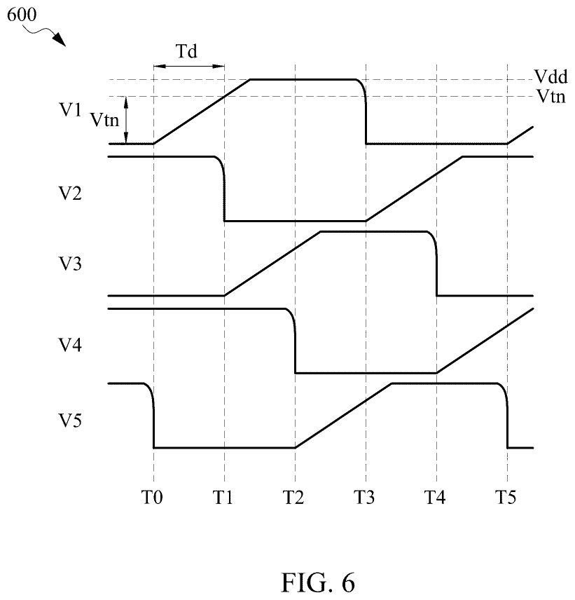

FIG. 6 illustrates waveforms 600 of various signals associated with operation of an example circuit, in accordance with various embodiments. For example, the waveforms 600 may be associated with the circuit 100, circuit 200, circuit 300, circuit 400, circuit 500, circuit 700, circuit 800, circuit 900, circuit 1000, etc. Accordingly, the following discussion of the waveforms 600 may refer to some of the reference numerals used in FIG. 1 to FIG. 5 as a non-limiting example. Further, the waveforms 600 are merely illustrated as an example, and are not intended to limit the present disclosure.

In some embodiments, the waveforms 600 may be associated with operation of the circuit 300. Here, as an example, the number (N) of transistors 320 is 5. The waveform V1 can be a voltage signal associated with the transistor 320A, the waveform V2 can be a voltage signal associated with the transistor 320B, the waveform V3 can be a voltage signal associated with the transistor 320C, the waveform V4 can be a voltage signal associated with the transistor 320D, and the waveform V5 can be a voltage signal associated with the transistor 320N. For example, each of the waveforms 600 may be an output from a corresponding one of the transistors 320 and/or a voltage level at the first source/drain terminal.

As discussed with respect to FIG. 1 to FIG. 5, for each of the transistors (e.g., the transistor 320A), the first source/drain terminal can be connected to the gate terminal of a first neighboring one (e.g., the transistor 320B) of the transistors, the second source/drain terminal can be connected to ground, and the gate terminal can be connected to the source/drain terminal of a second neighboring one (e.g., the transistor 320N) of the transistors. In some embodiments, the transistors 320 can be configured to provide the waveforms 600, each of which can be a delayed version of each other. For example, the waveform V1 is a waveform delayed, by a delay constant, from the waveform V2, which is a waveform delayed, by the delay constant, from the waveform V3, and so on. This can cause the waveforms 600 to form a set of delayed signals, thereby forming an oscillating signal.

As shown in FIG. 6, the waveform V2 is configured to fall in response to the waveform V1 rising to the threshold voltage Vtn at T1, while causing the waveform V3 to start rising. When the waveform V1 reaches a voltage level VDD, the waveform V1 is saturated. The waveform V4 is configured to fall in response to the waveform V3 rising to the threshold voltage Vtn at T2, while causing the waveform V5 to start rising. When the waveform V3 reaches the voltage level VDD, the waveform V3 is saturated. The waveform V1 is configured to fall in response to the waveform V5 rising to the threshold voltage Vtn at T3, while causing the waveform V2 to start rising. When the waveform V5 reaches the voltage level VDD, the waveform V5 is saturated. The waveform V3 is configured to fall in response to the waveform V2 rising to the threshold voltage Vtn at T4, while causing the waveform V4 to start rising. When the waveform V2 reaches the voltage level VDD, the waveform V2 is saturated. The waveform V5 is configured to fall in response to the waveform V4 rising to the threshold voltage Vtn at T4, while causing the waveform V1 to start rising. When the waveform V4 reaches the voltage level VDD, the waveform V4 is saturated. This can thereby form a set of delayed signals with a delay constant Td, while forming an oscillating signal with a period associated with the delay constant Td.

In some embodiments, the delay constant Td is associated with a capacitance of the capacitors 330. As shown, each of the waveforms 600 is delayed from each other by the delay constant Td. In some embodiments, the delay constant Td can be defined as RC, where C is the capacitance of the capacitors 330. Since the reference current IREF can be given as Vtn/R, and the time associated with the capacitors 330 (e.g., the time to charge the load capacitor to the threshold voltage) can be given as CVtn/IREF, the delay constant Td can be RC. In some embodiments, the waveforms 600, which is a set of the delayed signals, can form an oscillating signal with a period. The period can be defined as the number of transistors 320 multiplied by the delay constant Td. For example, here when N=5, the oscillating signal can have a period of 5×RC. As discussed above, in some embodiments, the number of transistors N can be a prime number (e.g., 2, 3, 5, 7, etc.). In some embodiments, the number of transistors N can be an odd number.

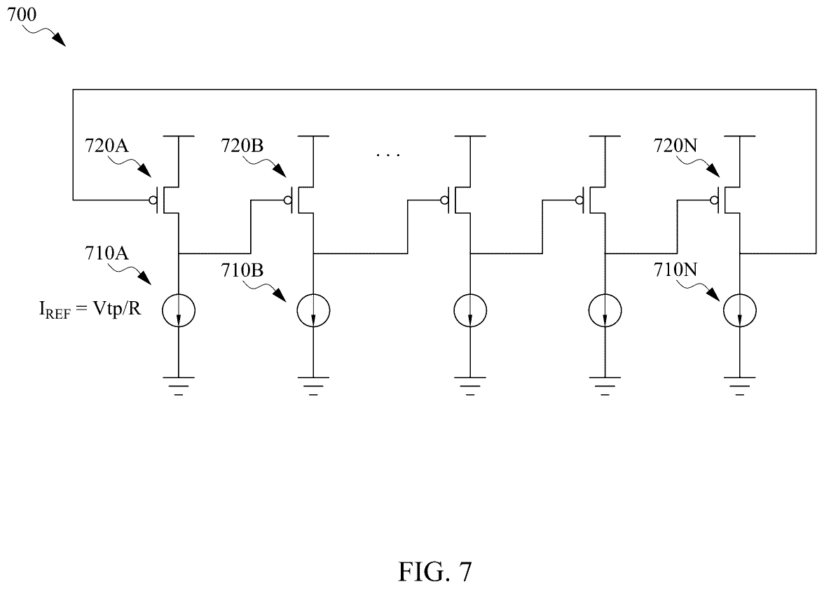

FIG. 7 illustrates an example circuit 700 that can be included in the memory circuit 100, in accordance with various embodiments. The circuit 700 can include a current source 710 (710A, 710B, . . . , 710N) and transistors 720 (720A, 720B, . . . , 720N), which may be substantially similar to and/or incorporate features of the current source 110 and the transistors 120, respectively. Shown in FIG. 7 is a non-limiting example, and the circuit 700 can include more, fewer, or different components than shown in or described with respect to FIG. 7. Referring to FIG. 7, in some embodiments, the circuit 700 can be configured based on p-type transistors. For example, the transistors 720 can be p-type MOS transistors.

The current source 710 can be configured to provide a reference current IREF. In some embodiments, the reference current IREF can be proportional to a threshold voltage Vtn of the transistors 720. For example, as shown, the reference current IREF can be Vtp/R. The transistors 720 can be configured to receive the reference current IREF from the current source 710. In some embodiments, as shown, each of the transistors 720 is connected to a corresponding one of the current source 710 and receive the reference current IREF therefrom.

In some embodiments, the transistors 720 can have a same conductive type. For example, the transistors 720 can be p-type transistors. In some embodiments, the transistors 720 can include only one type of transistors. For example, each of the transistors 720 can be a p-type MOS transistor.

In some embodiments, the transistors 720 can be or include a plurality of transistors connected to each other. In some embodiments, as shown, the transistors 220 can form a loop, such that the transistors are connected in a circular arrangement. In some embodiments, each of the transistors 720 can include a first source/drain terminal connected to a gate terminal of a first neighboring one of the transistors 720, a second source/drain terminal connected to ground, and a gate terminal connected to a source/drain terminal of a second neighboring one of the transistors 720. For example, the first source/drain terminal of the transistor 720A is connected to the gate terminal of a first neighboring transistor (e.g., the transistor 720B). The second source/drain terminal of the transistor 720A is connected to ground. The gate terminal of the transistor 720A is connected to the source/drain terminal of a second neighboring transistor (e.g., the transistors 720N).

In some embodiments, the circuit 700 can be configured to serve as a ring oscillator. The transistors 720 can be configured to provide oscillating signals. For example, the transistor 720A can be configured to provide a first signal, and the transistor 720B can be configured to provide a second signal being a delayed version of the first signal. In some embodiments, the transistors 720 can be configured to provide oscillating signals without connecting to an inverter.

Although depicted to include five transistors (e.g., N=5), the circuit 700 can include a certain number of transistors 720. In some embodiments, the number of transistors 720 can be a prime number (e.g., 2, 3, 5, 7, etc.). This can prevent two or more signals from being harmonized. In some embodiments, the number of transistors 720 can be an odd number.

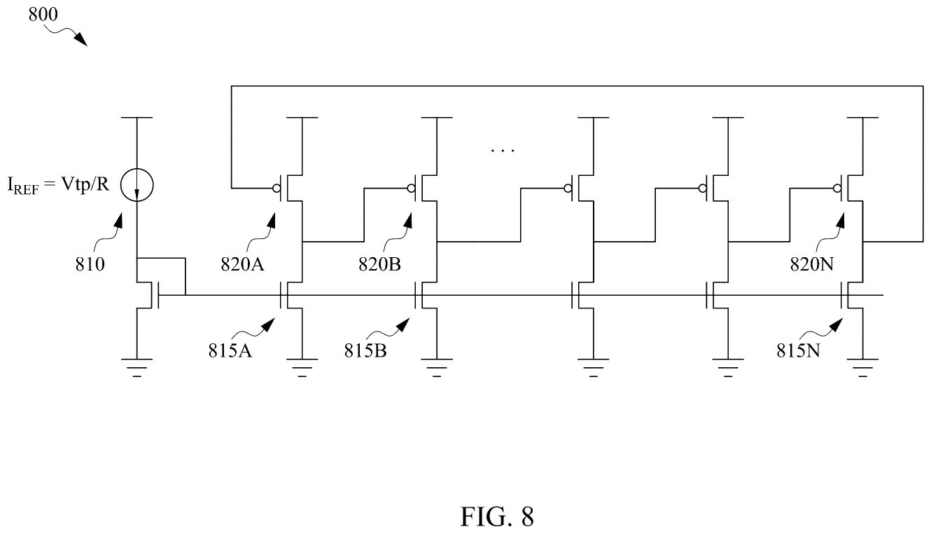

FIG. 8 illustrates an example circuit 800 that can be included in the memory circuit 100, in accordance with various embodiments. In some embodiments, the circuit 800 may be substantially similar to and/or incorporate features of the circuit 100, the circuit 700, etc. The circuit 800 can include a current source 810, first transistors 820 (820A, 820B, . . . , 820N), second transistors 815 (815A, 815B, . . . , 815N), capacitors (not shown), etc. Shown in FIG. 8 is a non-limiting example, and the circuit 800 can include more, fewer, or different components than shown in or described with respect to FIG. 8.

The current source 810 can be configured to provide a reference current IREF. In some embodiments, the current source 810 can provide the reference current IREF through a current mirror. The current mirror can be connected between the current source 810 and the first transistors 820. In some embodiments, the current mirror can include the second transistors 815. As shown, each of the second transistors 815 can be connected to a corresponding one of the first transistors 820. In some embodiments, the second transistors 815 can have a conductive type opposite to the conductive type of the first transistors 820. For example, the first transistors 820 are p-type MOS transistors, and the second transistors 815 are n-type MOS transistors.

In some embodiments, the current source 810 can provide the reference current IREF proportional to a threshold voltage Vtp of the first transistors 820 to each of the first transistors 820. For example, as shown, the reference current IREF can be Vtp/R.

In some embodiments, the first transistors 820 can be or include a plurality of transistors connected to each other, while connected to other components. In some embodiments, each of the first transistors 820 can include a first source/drain terminal connected to a gate terminal of a first neighboring one of the first transistors 820, a second source/drain terminal connected to ground, and a gate terminal connected to a source/drain terminal of a second neighboring one of the first transistors 820. For example, the first source/drain terminal of the first transistor 820A is connected to the gate terminal of a first neighboring transistor (e.g., the first transistor 820B). The second source/drain terminal of the first transistor 820A is connected to ground. The gate terminal of the first transistor 820A is connected to the source/drain terminal of a second neighboring transistor (e.g., the first transistors 820N).

In some embodiments, although not shown, capacitors (e.g., similar to the capacitors 330) can be connected to the first source/drain terminal of each of the first transistors 820. The capacitors can be purposedly added load capacitors. In some embodiments, the capacitors can be connected to the gate terminal of each of the first transistors 820. For example, each of the first source/drain terminal of the first transistor 820A and the gate terminal of the first transistor 820B can be connected to the capacitor. In some embodiments, the capacitors can be omitted, as shown. In some embodiments, the capacitors can represent other capacitance (e.g., wire, parasitic, etc.).

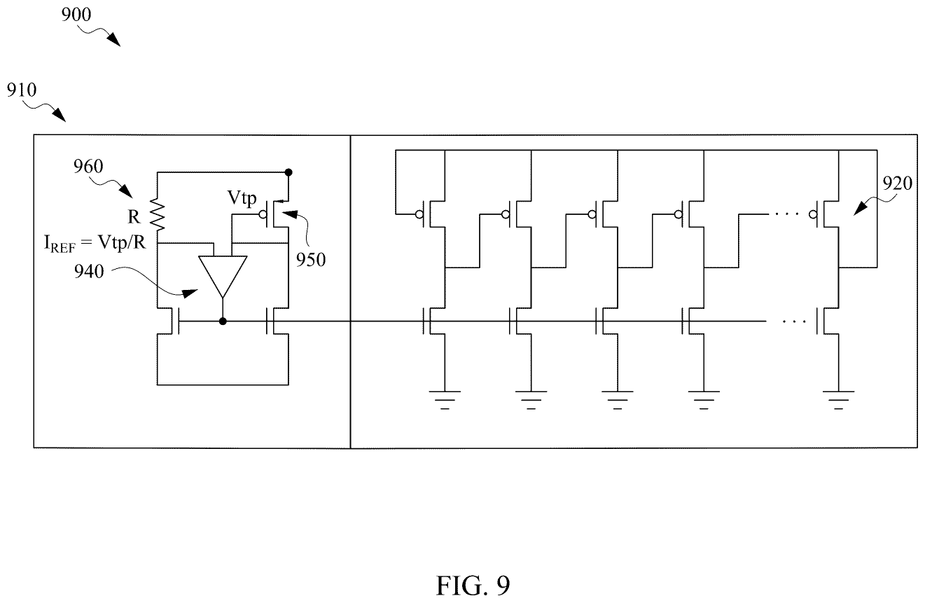

FIG. 9 illustrates an example circuit 900 that can be included in the memory circuit 100, in accordance with various embodiments. In some embodiments, the circuit 900 may be substantially similar to and/or incorporate features of the circuit 100, the circuit 700, the circuit 800, etc. The circuit 900 can include a current source 910 and transistors 920, may be substantially similar to and/or incorporate features of the current source 110 (and/or the current source 710, the current source 810, etc.) and the transistors 920 (and/or the transistors 720, the transistors 820, etc.), respectively. Shown in FIG. 9 is a non-limiting example, and the circuit 900 can include more, fewer, or different components than shown in or described with respect to FIG. 9.

The current source 910 can include various components configured to provide a reference current IREF to the transistors 920. In some embodiments, the current source 910 can include an operational amplifier 940, a diode-connected transistor 950, a resistor 960, which can be configured to provide the reference current IREF to the transistors 920. In some embodiments, as shown, the operational amplifier 940 can be connected to the diode-connected transistor 950. In some embodiments, the diode-connected transistor 950 can have a threshold voltage (Vtp), the same as the threshold voltage of the transistors 920. In some embodiments, as shown, the operational amplifier 940 can be connected to the resistor 960 having a resistance of (R), such that the operational amplifier 940 can force the voltage across the resistor 960 to be equal to the threshold voltage of the diode-connected transistor 950. The operational amplifier 940 can be thereby configured to output the reference current IREF based on the threshold voltage (Vtp) of the diode-connected transistor 950. For example, the current source 910 can be configured for the operational amplifier 940 to output the reference current IREF of Vtp/R.

In some embodiments, the transistors 920 can have the same threshold voltage Vtp as the diode-connected transistor 950. The transistors 920 can be of the same type as the transistor 950. The transistors 920 can have a same size and/or a fixed ratio as that of the transistor 950. In some embodiments, the transistors 920 can be a multiple or fractional of the size of transistor 950.

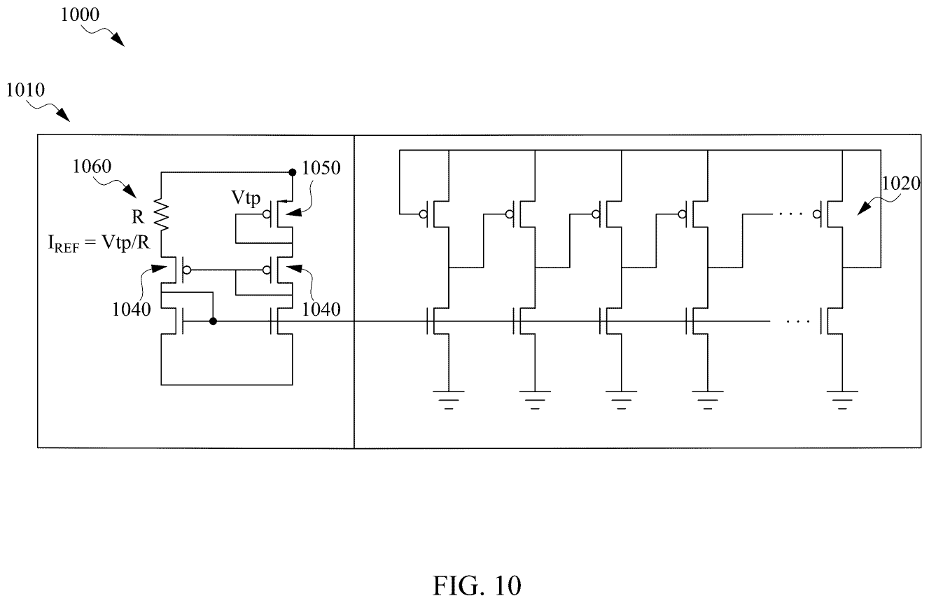

FIG. 10 illustrates an example circuit 1000 that can be included in the memory circuit 100, in accordance with various embodiments. In some embodiments, the circuit 1000 may be substantially similar to and/or incorporate features of the circuit 100, the circuit 700, the circuit 800, etc. The circuit 1000 can include a current source 1010 and transistors 1020, may be substantially similar to and/or incorporate features of the current source 110 (and/or the current source 710, the current source 810, etc.) and the transistors 120 (and/or the transistors 720, the transistors 820, etc.), respectively. Shown in FIG. 10 is a non-limiting example, and the circuit 1000 can include more, fewer, or different components than shown in or described with respect to FIG. 10.

The current source 1010 can include various components configured to provide a reference current IREF to the transistors 1020. In some embodiments, the current source 1010 can include a diode-connected transistor 1050, reference transistors 1040, a resistor 1060, which can be configured to provide the reference current IREF to the transistors 1020.

In some embodiments, the reference transistors 1040 can have a conductive type the same as the conductive type of the transistors 1020. For example, both the transistors 1020 and the reference transistors 1040 are p-type MOS transistors.

In some embodiments, as shown, the reference transistors 1040 can be connected to the diode-connected transistor 1050. In some embodiments, the diode-connected transistor 1050 can have a threshold voltage (Vtp), the same as the threshold voltage of the transistors 1020. In some embodiments, as shown, the reference transistors 1040 can be connected to the resistor 1060 having a resistance of (R), such that the reference transistors 1040 can force the voltage across the resistor 1060 to be equal to the threshold voltage of the diode-connected transistor 1050. The current source 1010 can be configured to output the reference current IREF based on the threshold voltage of the diode-connected transistor (Vtp), for example, Vtp/R.

In some embodiments, the transistors 1020 can have the same threshold voltage Vtp as the diode-connected transistor 1050. The transistors 1020 can be of the same type as the transistor 1050. The transistors 1020 can have a same size and/or a fixed ratio as that of the transistor 1050. In some embodiments, the transistors 1020 can be a multiple or fractional of the size of transistor 1050.

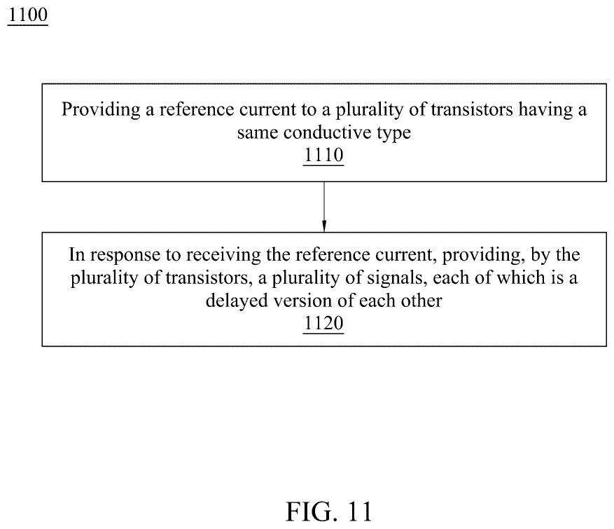

FIG. 11 illustrates a flow chart of an example method 1100 for operating a memory circuit (e.g., 100 of FIG. 1), in accordance with some embodiments. It is noted that the method 1100 is merely an example and is not intended to limit the present disclosure. Accordingly, it is understood that additional operations may be provided before, during, and after the method 1100 of FIG. 11, and that some other operations may only be briefly described herein.

In a brief overview, the method 1100 starts with operation 1110 of providing a reference current to a plurality of transistors having a same conductive type. The method 1100 continues to operation 1120 of, in response to receiving the reference current, providing, by the plurality of transistors, a plurality of signals, each of which is a delayed version of each other.

At operation 1110, a current source (e.g., the current source 110) can provide a reference current (e.g., the reference current IREF) to a plurality of transistors (e.g., the transistors 120) having a same conductive type (e.g., n-type, p-type). In some embodiments, the reference current can be proportional to a threshold voltage (e.g., Vtn, Vtp, etc.) of the plurality of transistors.

At operation 1120, the transistors can provide a plurality of signals (e.g., the waveforms 600), in response to receiving the reference current. In some embodiments, each of the plurality of signals can be a delayed version of each other. In some embodiments, when a first one of the plurality of signals rises to the threshold voltage, a second signal can be configured to fall. In some embodiments, each of the plurality of signals can be delayed from each other by a delay constant (e.g., the delay constant Td) associated with a capacitor (e.g., the capacitors 330) connected to the plurality of transistors.

In one aspect of the present disclosure, a circuit is disclosed. The circuit includes a current source configured to provide a reference current, a plurality of transistors each configured to receive the reference current from the current source. Each of the plurality of transistors has a same conductive type and includes a first source/drain terminal connected to a gate terminal of a first neighboring one of the transistors, a second source/drain terminal connected to ground, and a gate terminal connected to a source/drain terminal of a second neighboring one of the transistors.

In another aspect of the present disclosure, a circuit is disclosed. A circuit includes a current source configured to provide a reference current and a plurality of transistors each configured to receive the reference current from the current source. Each of the plurality of transistors has a same conductive type, and the reference current is proportional to a threshold voltage of the plurality of transistors. The plurality of transistors include a first transistor configured to provide a first signal and a second transistor configured to provide a second signal being a delayed version of the first signal. The second signal falls in response to the first signal rising to the threshold voltage.

In yet another aspect of the present disclosure, a method is disclosed. The method includes providing a reference current to a plurality of transistors having a same conductive type, wherein the reference current is proportional to a threshold voltage of the plurality of transistors, and in response to receiving the reference current, providing, by the plurality of transistors, a plurality of signals, each of which is a delayed version of each other, wherein when a first one of the plurality of signals rises to the threshold voltage, a second signal falls.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a current source configured to provide a reference current;
a plurality of transistors each configured to receive the reference current from the current source, wherein each of the plurality of transistors has a same conductive type and includes:
a first source/drain terminal connected to a gate terminal of a first neighboring one of the plurality of transistors;
a second source/drain terminal connected to ground; and
a gate terminal connected to a source/drain terminal of a second neighboring one of the plurality of transistors.

2. The circuit of claim 1, wherein the plurality of transistors form a loop.

3. The circuit of claim 1, further comprising a plurality of capacitors, wherein each of the plurality of capacitors is connected to the first source/drain terminal of each of the plurality of transistors.

4. The circuit of claim 3, wherein the plurality of transistors are configured to provide a plurality of signals, each of which is a delayed version of each other, wherein a delay constant is associated with a capacitance of a corresponding one of the plurality of capacitors.

5. The circuit of claim 1, further comprising a current mirror connected between the current source and the plurality of transistors.

6. The circuit of claim 5, wherein the current mirror includes a plurality of second transistors each of which is connected to a corresponding one of the plurality of transistors, wherein the plurality of second transistors have a conductive type opposite to the conductive type of the plurality of transistors.

7. The circuit of claim 1, wherein a number of the plurality of transistors is a prime number.

8. The circuit of claim 1, wherein the current source includes an operational amplifier and a diode-connected transistor, wherein the operational amplifier is configured to output the reference current based on a threshold voltage of the diode-connected transistor.

9. The circuit of claim 1, wherein the current source includes a diode-connected transistor and reference transistors that have a conductive type the same as the conductive type of the plurality of transistors, wherein the current source is configured to output the reference current based on a threshold voltage of the diode-connected transistor.

10. The circuit of claim 1, wherein the plurality of transistors are configured to provide oscillating signals without connecting to an inverter.

11. A circuit, comprising:
a current source configured to provide a reference current;
a plurality of transistors each configured to receive the reference current from the current source, wherein each of the plurality of transistors has a same conductive type, and the reference current is proportional to a threshold voltage of the plurality of transistors, the plurality of transistors including:
a first transistor configured to provide a first signal; and
a second transistor configured to provide a second signal being a delayed version of the first signal, wherein the second signal falls in response to the first signal rising to the threshold voltage.

12. The circuit of claim 11, wherein the plurality of transistors form a loop.

13. The circuit of claim 11, further comprising a plurality of capacitors connected between the plurality of transistors.

14. The circuit of claim 13, wherein the second signal is delayed from the first signal by a delay constant associated with a capacitance of the plurality of capacitors.

15. The circuit of claim 11, further comprising a current mirror connected between the current source and the plurality of transistors.

16. The circuit of claim 11, wherein a number of the plurality of transistors is a prime number.

17. The circuit of claim 11, wherein the current source includes an operational amplifier and a diode-connected transistor, wherein the operational amplifier is configured to output the reference current based on a threshold voltage of the diode-connected transistor.

18. The circuit of claim 11, wherein the current source includes a diode-connected transistor and reference transistors that have a conductive type the same as the conductive type of the plurality of transistors, wherein the current source is configured to output the reference current based on a threshold voltage of the diode-connected transistor.

19. A method, comprising:
providing a reference current to a plurality of transistors having a same conductive type, wherein the reference current is proportional to a threshold voltage of the plurality of transistors; and
in response to receiving the reference current, providing, by the plurality of transistors, a plurality of signals, each of which is a delayed version of each other, wherein when a first one of the plurality of signals rises to the threshold voltage, a second signal falls.

20. The method of claim 19, wherein each of the plurality of signals is delayed from each other by a delay constant associated with a capacitor connected to the plurality of transistors.
